(19) United States
(12) Patent Application Publication
(10) Pub. No.: US 2012/0234586 A1
(43) Pub. Date: Sep. 20, 2012

(54) PROCESS FOR FORMING FLEXIBLE SUBSTRATES USING PUNCH PRESS TYPE TECHNIQUES

(75) Inventors: JOHN TELLE, Albuquerque, NM (US); Brian J. Murphy, Albuquerque, NM (US); David H. Meakin, Albuquerque, NM (US)

(73) Assignee: APPLIED MATERIALS, INC., Santa Clara, CA (US)

(21) Appl. No.: 13/419,967

(22) Filed: Mar. 14, 2012

Related U.S. Application Data
(60) Provisional application No. 61/454,382, filed on Mar. 18, 2011.

(51) Int. Cl. H05K 1/09; H05K 3/10; H05K 1/02; H05K 1/03; H05K 1/00

(52) U.S. Cl. 174/257; 174/256; 174/258; 174/259; 29/846

(57) ABSTRACT

Embodiments of the invention generally relate to methods of forming flexible substrates for use in photovoltaic modules. The methods include shaping a metal foil and adhering the metal foil to a flexible backsheet. An optional interlayer dielectric and anti-tarnish material may then be applied to the upper surface of the shaped metal foil disposed on the flexible backsheet. The metal foil may be shaped using die cutting, roller cutting, or laser cutting techniques. The die cutting, roller cutting, and laser cutting techniques simplify the flexible substrate formation processes by eliminating resist-printing and etching steps previously used to pattern metal foils. Additionally, the die cutting, roller cutting, and laser cutting techniques reduce the consumption of consumable materials previously used in the patterning of metal foils.

### CROSS-REFERENCE TO RELATED APPLICATIONS

This application claims benefit of U.S. Provisional Patent Application Ser. No. 61/454,382, filed Mar. 18, 2011, which is herein incorporated by reference.

### BACKGROUND OF THE INVENTION

1. Field of the Invention

Embodiments of the invention generally relate to methods of forming flexible substrates for use in photovoltaic modules.

2. Description of the Related Art

Solar cells are photovoltaic devices that convert sunlight into electrical power. Each solar cell generates a specific amount of electric power and is typically tiled into an array of interconnected solar cells that are sized to deliver a desired amount of generated electrical power. The most common solar cell base material is silicon, which is in the form of single crystal or polycrystalline substrates. Because the amortized cost of forming silicon-based solar cells to generate electricity is higher than the cost of generating electricity using traditional methods, there has been an effort to reduce the cost to form solar cells and the solar cell modules in which they are housed.

The typical fabrication sequence of photovoltaic modules using silicon solar cells includes the formation of the solar cell circuit, assembly of the layered structure (glass, polymer, solar cell circuit, polymer, backsheet), and then lamination of the layered structure. The solar cell circuit generally includes a thin sheet of patterned conductive material having a desired contact configuration. The solar cell circuit is patterned by coating a sheet of conductive foil with an etching resist, exposing the patterned foil to an etchant to etch the foil into a desired configuration, and then removing the remaining resist from the circuit. The circuit is then picked up using a robot, and positioned on the backsheet.

Etching of the conductive foil is not only time consuming, but it is relatively expensive in that it requires additional processing steps and equipment (e.g., screen printing apparatus to print the resist, a means of etching the conductive foil, and a resist removal step. Furthermore, resist materials and etchants are consumable materials which must be replenished.

Therefore, there is a need for a cheaper, more efficient method of forming flexible substrates having circuits for use in photovoltaic modules.

### SUMMARY OF THE INVENTION

Embodiments of the invention generally relate to methods of forming flexible substrates for use in photovoltaic modules. The methods include shaping a metal foil before adhering the metal foil to a flexible backsheet. An optional interlayer dielectric and anti-tarnish material may then be applied to the upper surface of the shaped metal foil disposed on the flexible backsheet. The metal foil may be shaped using die cutting, roller cutting, or laser cutting techniques. The die cutting, roller cutting, and laser cutting techniques simplify the flexible substrate formation processes by eliminating resist-printing and etching steps previously used to pattern metal foils. Additionally, the die cutting, roller cutting, and laser cutting techniques reduce the consumption of consumable materials previously used to shape metal foils.

In one embodiment, a method of forming a flexible substrate for use in photovoltaics comprises positioning a metal foil within a punch press and actuating the punch press to shape the metal foil. A flexible backsheet is then positioned adjacent to the shaped metal foil within the punch press. An adhesive is then applied to the flexible backsheet or the shaped metal foil. Pressure is then applied to the flexible backsheet, the shaped metal foil, and the adhesive to adhere the shaped metal foil to the flexible backsheet.

In another embodiment, a method of forming a flexible substrate for use in photovoltaics comprises applying an adhesive to the upper surface of a flexible backsheet. The adhesive is positioned adjacent to a metal foil, and a predetermined shape is formed in the metal foil using a laser. The shaped metal foil is disposed on the adhesive, and the shaped metal foil is bonded to the flexible backsheet. An interlayer dielectric is then disposed on the shaped metal foil. The interlayer dielectric has openings therethrough. An anti-tarnishing material is then disposed on the shaped metal foil within the openings of the interlayer dielectric layer.

In another embodiment, a method of forming a flexible substrate for use in photovoltaics comprises positioning a flexible backsheet and a metal foil between a support roller and a rotary die. An adhesive is then disposed on the flexible backsheet, and the metal foil is then shaped using the rotary die. The shaped metal foil is then adhered to the flexible backsheet while passing the flexible backsheet, the shaped metal foil, and the adhesive between the support roller and the rotary die. An interlayer dielectric is then applied to the shaped metal foil. The interlayer dielectric has openings therethrough. An anti-tarnishing material is then applied to the shaped metal foil through the openings in the interlayer dielectric.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of a system for forming flexible substrates according to one embodiment of the invention.

FIG. 2 illustrates a flow diagram of a method of forming a flexible substrate using the system shown in FIG. 1 according to one embodiment of the invention.

FIGS. 3A and 3B are schematic illustrations of a system for forming flexible substrates according to another embodiment of the invention.

FIG. 4 illustrates a flow diagram of a method of forming a flexible substrate using the system shown in FIGS. 3A and 3B according to one embodiment of the invention.

FIG. 5 is a schematic illustration of a system for forming flexible substrates according to another embodiment of the invention.

FIG. 6 illustrates a flow diagram of a method of forming a flexible substrate using the system shown in FIG. 5 according to one embodiment of the invention.

FIG. 7 is a schematic illustration of a system for forming flexible substrates according to another embodiment of the invention.

FIG. 8 illustrates a flow diagram of a method of forming a flexible substrate using the system shown in FIG. 7 according to one embodiment of the invention.

FIGS. 9A and 9B are schematic illustrations of a shaped metal foil which may be formed according to embodiments of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention generally relate to methods of forming flexible substrates for use in photovoltaic modules. The methods include shaping a metal foil before adhering the metal foil to a flexible backsheet. An optional interlayer dielectric and anti-tarnish material may then be applied to the upper surface of the shaped metal foil disposed on the flexible backsheet. The metal foil may be shaped using die cutting, roller cutting, or laser cutting techniques. The die cutting, roller cutting, and laser cutting techniques simplify the flexible substrate formation processes by eliminating resist-printing and etching steps previously used to pattern metal foils. Additionally, the die cutting, roller cutting, and laser cutting techniques reduce the consumption of consumable materials previously used in the shaping of metal foils. The term “flexible substrate” as used herein generally refers to a multi-layered substrate suitable for use in roll-to-roll processing systems.

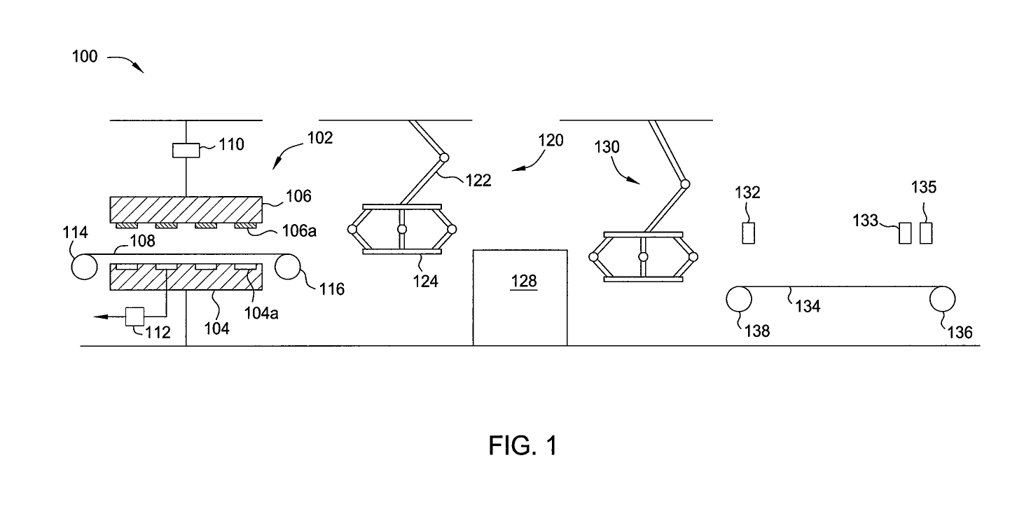

FIG. 1 is a schematic illustration of a system 100 for forming flexible substrates according to one embodiment of the invention. The system 100 includes a punch press 102, two robots 120, 130, and a magazine 128. The punch press 102 includes a die block 104 and a punch block 106. The die block 104 includes a female portion 104a of the die set, while the punch block 106 includes a male portion 106a of a die set. The female portion 104a and the male portion 106a correspond to a shape to be formed in a metal foil 108 positioned therebetween. The punch block 106 is actuatable towards the die block 104 by an actuator 110 so that the male portion 106a of the die set may punch through the metal foil 108 and enter the female portion 104a, thus forming a shape in the metal foil 108. A vacuum device 112 connected to the die block 104 assists in maintaining proper alignment of the metal foil 108 during the punch process by applying vacuum pressure through openings disposed in the die block 104. A metal foil feed roller 114 is adapted to provide the metal foil 108 for a punch process in the punch press 102, while the metal foil take-up roller 116 is adapted to take-up scrap metal foil remaining from the punch process.

A robot 120 is positioned downstream of the punch press 102. The robot 120 includes an arm 122 and a vacuum gripper 124. The robot 120 has sufficient range to remove a piece of shaped metal foil from the die block 104 of the punch press 102 and dispose the shaped metal foil in a magazine 128 positioned downstream of the robot 120. The magazine 128 is adapted to contain a stack of shaped metal foils for use in subsequent processing. A robot 130, similar to robot 120, is positioned downstream of the magazine 128. The robot 120 is adapted to remove a shaped foil from the magazine 128 and position the shaped metal foil on a flexible backsheet 134. An adhesive applicator 132 is located adjacent to the surface of the flexible backsheet 134 for applying an adhesive to the flexible backsheet 134 prior to placement of the shaped metal foil. Additionally, a dielectric applicator 133 and an anti-tarnish applicator 135 are positioned down stream of the adhesive applicator 132 for applying a dielectric material and an anti-tarnish material to the exposed surface of the shaped metal foil. A take-up roller 136 is adapted to take up the flexible backsheet 134 having the shaped metal foil thereon, while a feed roller 138 provides fresh flexible backsheet 134 for positioning of a subsequent metal foil from the magazine 128.

The adhesive applicator 132, the dielectric applicator 133, and the anti-tarnish applicator 135 are screen printing devices adapted to apply a respective material to the upper surface of the shaped metal foil. However, it is contemplated that any application device, including rollers, may be beneficially utilized to apply material to the shaped metal foil.

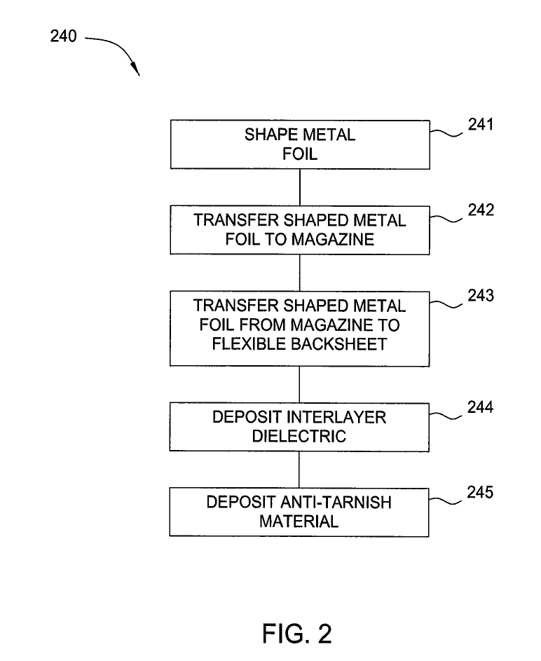

FIG. 2 illustrates a flow diagram 240 of a method of forming a flexible substrate using the system 100 shown in FIG. 1 according to one embodiment of the invention. Flow diagram 240 begins at step 241. In step 241, a metal foil is unrolled from a feed roller and positioned between a die set located in a punch press. The metal foil is formed from aluminum and has a thickness within a range from about 10 microns to about 80 microns; for example, about 60 microns to about 65 microns. A vacuum is applied using a vacuum source through openings positioned in the die block of the punch press to chuck the metal foil to the die block. The vacuum reduces movement of the metal foil on the die block during the punch process thereby increasing accuracy and consistency of the punch process. During the punch process, a punch is actuated towards the metal foil to form a predetermined shape, such as a circuit, in the metal foil. The punch is then retracted from the die block to expose the shaped metal foil. The punch typically removes about ten percent or less of the metal foil during the punch process.

In step 242, vacuum grippers connected to a robot are positioned between the punch and die block of the punch press. The vacuum grippers are placed in contact with the shaped metal foil, and vacuum is applied through the vacuum grippers to chuck the shaped metal foil to the robot. The vacuum applied through the die block of the punch press is halted to release the shaped metal foil to the robot. The robot then transfers the shaped metal foil to a magazine of shaped metal foils for storage or transportation of the shaped metal foils. Contemporaneously with the transfer of the shaped metal foil by the robot, feed and take up rollers index the metal foil located between the punch and die so that fresh metal foil is located within the punch press for a subsequent punching process.

In step 243, after a predetermined amount of time, a shaped metal foil from the magazine is picked up by a second robot for placement on a flexible backsheet. The flexible backsheet is formed from polyethelene terephthalate (PET) and has a thickness within a range from about 100 microns to about 200 microns. While the second robot is removing the shaped metal foil from the magazine, an adhesive applicator applies a pressure sensitive patterned adhesive (corresponding to the shape of the metal foil) to the upper surface of the flexible backsheet for bonding of the shaped metal foil. The pressure sensitive adhesive may be FLEXMARK® PM 500 (clear) available from Flexcon of Spencer, Mass., and may be applied to a thickness of about 5 microns. The robot then places the shaped metal foil on the pressure sensitive adhesive, and applies sufficient pressure to bond the shaped metal foil to the flexible backsheet. A backsheet feed roller then dispenses additional backsheet for placement of a subsequent shaped metal foil from the magazine, while a backsheet take-up roller rolls the flexible backsheet having the shaped metal foil thereon.

In step 244, after the backsheet feed roller and the backsheet take-up roller have positioned fresh backsheet material for a subsequent shaped metal foil adhesion, an interlayer dielectric material is screen printed on the shaped metal foil adhered to the flexible backsheet. The interlayer dielectric material is printed in a pattern substantially covering the shaped metal foil; however, openings are left therethrough to allow for electrical connections between the shaped metal foil and a solar cell subsequently positioned over the shaped metal foil. The interlayer dielectric is formed from an acrylic or phenolic polymer material, and is deposited to a thickness of about 25 microns. In step 245, an anti-tarnish material is disposed on the shaped metal foil in the areas not covered by the interlayer dielectric to prevent oxidation of the exposed areas of the shaped metal foil. The anti-tarnish material is a copper-containing material, such as metallic copper, or a tarnish inhibitor, such as ENTEK® CU 56, available from Enthone, Inc.

Flow diagram 240 illustrates one embodiment of forming flexible substrates for use in photovoltaics; however, other embodiments of forming flexible substrates are contemplated. In another embodiment, either or both of steps 244 and 245 may occur prior to step 241. In such an embodiment, the dielectric applicator and the anti-tarnish applicator are positioned upstream of the punch press. The punch press may be adapted to cut through both the metal foil and interlayer dielectric. In another embodiment, it is contemplated the metal foil may be bonded to a first layer of flexible backsheet, such as PET, prior to step 241 in order to provide additional rigidity to the shaped metal foil to assist in handling of the shaped metal foil. The metal foil and optionally the first layer of flexible backsheet bonded thereto may then be shaped in the punch press, and loaded into the magazine. Prior to placement of the shaped metal foil on a second flexible metal, the first layer of flexible backsheet is removed by a backsheet stripping device. However, it is also contemplated that the first layer of flexible backsheet may remain on the shaped metal foil, resulting in two layers of flexible backsheet bonded to one another in the final roll-to-roll product. The two layers of flexible backsheet may be bonded together using a pressure sensitive adhesive.

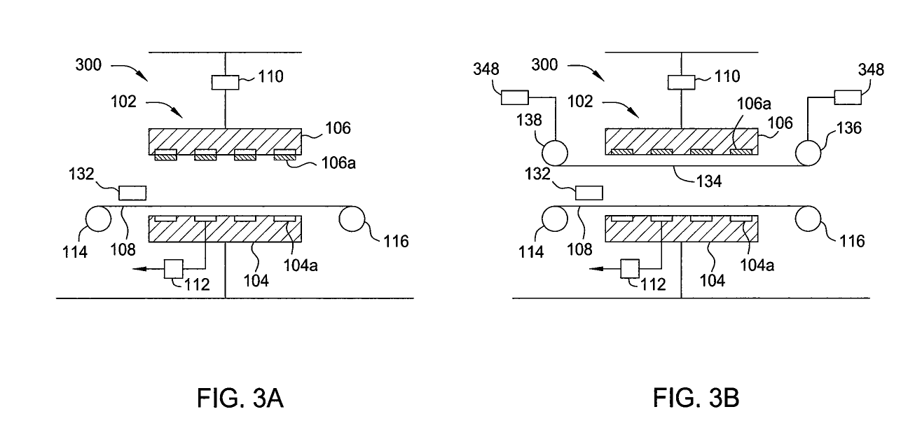

FIGS. 3A and 3B are schematic illustrations of a system 300 for forming flexible substrates according to another embodiment of the invention. FIG. 3A illustrates the system 300 in a punching position. The system 300 includes a punch press 102 and an adhesive applicator 132 positioned upstream of the punch press 102. The punch press 102 includes a die block 104 and a punch block 106 positioned adjacent to one another. The die block 104 includes a female portion 104a of the die set, while the punch block 106 includes a male portion 106a of the die set. The female portion 104a and the male portion 106a correspond to a shape to be formed in a metal foil 108 positioned therebetween.

An actuator 110 is adapted to actuate the male portion 106a beyond the lower surface of the punch block 106 to place the male portion 106a in a punching position, as shown. The punch block 106 is actuatable towards the die block 104 by the actuator 110 so that the male portion 106a of the die set may punch through the metal foil 108 and enter the female portion 104a. A vacuum device 112 connected to the die block 104 provides suction through openings within the die block 104 to chuck the metal foil 108 to the upper surface of the die block. A metal foil feed roller 114 is adapted to provide unused metal foil 108 for a punch process in the punch press 102, while the metal foil take-up roller 116 is adapted to take-up scrap metal foil remaining from the punch process.

FIG. 3B illustrates the system 300 in a bonding position. In the bonding position, the male portions 106a of the punch block 106 are recessed into the punch block 106 to form a lower planar surface of the punch block 106. The male portions are actuatable using the actuator 110. Additionally, a flexible backsheet 134, which is disposed on a feed roller 138 and take-up roller 136, is positioned between the punch block 106 and the die block 104. Actuators 348, such as stepper motors, are connected to the feed roller 138 and the take-up roller 136 and are adapted to laterally move the feed roller 138 and the take-up roller 136 to position the flexible backsheet 134 between the die block 104 and the punch block 106. An adhesive applicator 132 is positioned at the leading (i.e., upstream) edge of the flexible backsheet 134 and is adapted to apply an adhesive material to the flexible backsheet in a predetermined pattern as the backsheet material is unrolled form the feed roller 138.

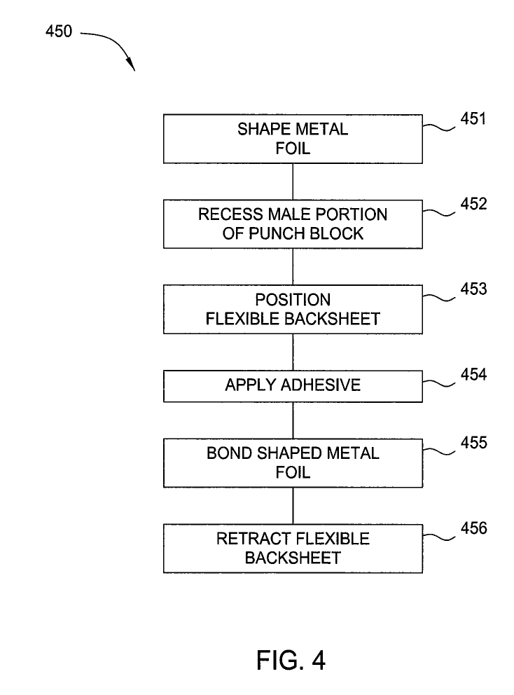

FIG. 4 illustrates a flow diagram 450 of a method of forming a flexible substrate using the system 300 shown in FIGS. 3A and 3B according to one embodiment of the invention. In step 451, a metal foil is unrolled from a feed roller and positioned between a die set located in a punch press. Once the metal foil is positioned, a vacuum is applied using a vacuum source through openings positioned in a die block of the punch press to chuck the metal foil to the die block. The vacuum reduces movement of the metal foil on the die block during the punch process to increase accuracy and consistency of the punch process. During the punch process, a punch is actuated towards the metal foil to form a predetermined shape in the metal foil. The punch is then retracted from the die block to expose the shaped metal foil.

In step 452, the male portion of the die set is retracted into the punch block to form a lower planar surface on the punch block. The male portion of the die set is retracted using an actuator coupled thereto. In step 453, a flexible backsheet is positioned between the punch block and the die block adjacent to the shaped metal foil which was punched in step 451. The flexible backsheet is positioned by actuation of the backsheet feed roller and the backsheet take-up roller along guide rails. The actuators, which are stepper motors adapted to provide incremental actuation, laterally move the flexible backsheet to a position above the shaped metal foil. The actuators should allow for consistent and repeatable positioning of the flexible backsheet to promote process uniformity.

In step 454, a pressure-sensitive adhesive is applied to the lower surface of the flexible backsheet by an adhesive applicator, such as a screen printing device. The pressure sensitive adhesive is applied in a predetermined pattern as the flexible backsheet is unrolled from the feed roller to position backsheet material above the shaped metal foil located on the die block.

In step 455, the punch block (having a lower planar surface) is actuated towards the die block to press the flexible backsheet to the shaped metal foil. The pressure sensitive adhesive, which is placed in contact with the shaped metal foil by actuation of the punch block, bonds the shaped metal foil to the flexible backsheet after a sufficient application of pressure. The punch block is then lifted from the die block releasing the pressure applied to the flexible backsheet and the shaped metal foil. As the punch block is lifted from the die block, vacuum pressure is maintained through openings disposed in the die block to suction the undesired portions of the metal foil to the die block. Thus, the probability of undesired portions of the metal foil bonding to the flexible backsheet due to over-application or misalignment of adhesive in step 454 is reduced.

In step 456, the flexible backsheet is moved laterally by actuation of the backsheet feed roller and backsheet take-up roller to displace the flexible backsheet from between the punch block and die block of the punch press. Simultaneously, the scrap metal foil remaining over the die block is rolled up on the metal foil take-up roller, while fresh metal foil is positioned over the die block from the metal foil feed roller. The process described in flow diagram 450 may then be repeated.

Flow diagram 450 illustrates one embodiment of forming flexible substrates for use in photovoltaics; however, other embodiments of forming flexible substrates are also contemplated. In another embodiment, step 454 may occur prior to step 451. When step 454 occurs prior to step 451, the adhesive may be printed on the backsheet at a location separate from the punch press. The backsheet can then be rolled up and transferred to the punch press for bonding of the shaped metal foil to the flexible backsheet. By pre-printing the adhesive on the flexible backsheet, the system 300 is simplified (since the adhesive applicator is located at another workstation). Additionally, the process of bonding the shaped metal foil to the flexible backsheet is expedited, since pre-printing can occur at another station, and thus is not dependent upon the process steps occurring at the punch press. However, when step 454 occurs prior to step 451, the adhesive should be selected so that the flexible backsheet with the adhesive thereon can be unrolled during processing, but still maintain enough adhesive qualities so that the shaped metal foil will be sufficiently adhered thereto in order to meet final device specifications.

In another embodiment, it is contemplated that step 454 may be altered so that the pressure sensitive adhesive may be applied to the metal foil instead of the flexible backsheet. In such an embodiment, the adhesive may be applied to the metal foil as the metal foil is being unrolled at the punch press, or alternatively, the adhesive may be applied at a work station different than the punch press. When the adhesive is applied to the metal foil prior to punching, the punch press should be adapted to punch through both the adhesive and the metal foil.

In another embodiment, it is contemplated that the punch press may be inverted such that the die block and the metal foil are located above the punch block and the flexible backsheet. Thus, the process surface of the flexible backsheet is facing upright. In such an embodiment, the vacuum openings within the die block may be used to hold the shaped metal foil against the die block while the flexible backsheet is positioned thereunder. By positioning the flexible backsheet so that the process surface of the flexible backsheet is facing upwards, additional process steps, such as printing of an interlayer dielectric or an anti-tarnish material, can be performed subsequent to placement of the shaped metal foil. Therefore, it would be unnecessary to reorient the flexible backsheet to perform additional processing steps thereon.

Additionally, although step 453 is described as laterally moving the flexible backsheet between the die block and punch block of the punch press, it is contemplated that any movement paradigm which allows for punching of the metal foil without punching of the flexible backsheet can be used. Thus, step 453 is not intended to be limited to side-to-side movement of the flexible backsheet.

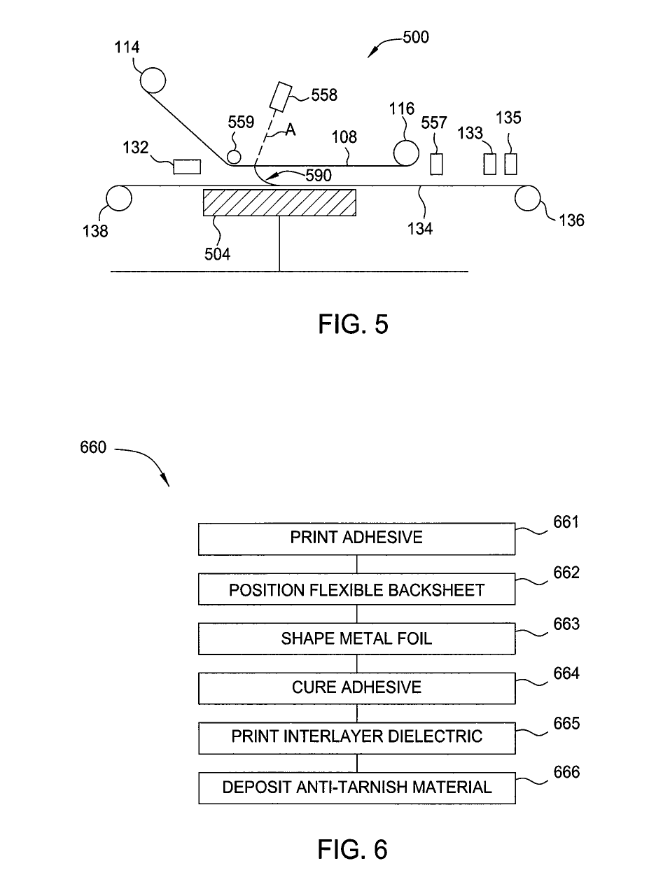

FIG. 5 is a schematic illustration of a system 500 for forming flexible substrates according to another embodiment of the invention. The system 500 includes a laser 558, a support table 504, and an adhesive applicator 132. A flexible backsheet 134 is shown extending between a feed roller 138 and a take-up roller 136. The flexible backsheet 134 is positioned over the support table 504 and beneath the metal foil 108. The support table 504 may include rollers or a movable belt to assist in moving the flexible backsheet 134 thereover. The metal foil 108 is bent around a guide roller 559 and extends between a metal foil feed roller 114 and a metal foil take-up roller 116. An adhesive applicator 132 is positioned upstream of the support table 504 and is adapted to apply a patterned adhesive to the flexible backsheet 134.

A laser 558, such as an Nd:YAG laser, is disposed adjacent to the upper surface of the metal foil 108. The laser 558 is positioned to direct a beam of electromagnetic radiation along path A to the surface of the metal foil 108. The laser 558 is adapted to form a predetermined shape in the metal foil, resulting in a shaped metal foil 590, for adherence to the flexible backsheet 134. An adhesive curing device 557, such as an ultraviolet (UV) lamp, is positioned downstream of the laser 558 for curing the patterned adhesive. A dielectric applicator 133 and an anti-tarnish applicator 135 are positioned downstream of the adhesive curing device 557, and are adapted to apply an interlayer dielectric and an anti-tarnishing material, respectively.

Although the laser 558 is described as an Nd:YAG laser, it is contemplated that other lasers, such as a CO₂ laser, may also be used. Additionally, it is also contemplated that the guide roller 559 may be omitted, and that the metal foil 108 may be positioned substantially parallel to the flexible backsheet 134.

FIG. 6 illustrates a flow diagram 660 of a method of forming a flexible substrate according to another embodiment of the invention. In step 661, an adhesive is screen printed in a predetermined patterned on an upper surface of a flexible backsheet. In step 662, the flexible backsheet and the adhesive thereon are positioned over a support table beneath a metal foil. In step 663, as the leading edge of the patterned adhesive moves proximate to the path A of a laser, the laser cuts a shape, such as a circuit pattern, into the metal foil located above the patterned adhesive on the flexible backsheet. The portion of the circuit pattern which is cut free from the metal foil contacts the patterned adhesive due to gravity. As the flexible backsheet and the metal foil are each moved downstream, additional metal foil is cut by the laser until the complete pattern is cut from the metal foil and disposed on the flexible backsheet.

In step 664, the shaped metal foil disposed on the flexible backsheet is moved adjacent to an adhesive curing device to cure the patterned adhesive located between the shaped metal foil and the flexible backsheet. In step 665, after the adhesive has been cured, an interlayer dielectric material is printed on the shaped metal foil using a dielectric applicator, such as a screen printer. The interlayer dielectric is applied in a pattern substantially covering the shaped metal foil; however, openings are left therethrough to allow for electrical connections between the shaped metal foil and a solar cell subsequently positioned over the shaped metal foil. In step 666, an anti-tarnish material is disposed on the shaped metal foil in the areas not covered by the interlayer dielectric to prevent oxidation of the exposed areas of the shaped metal foil.

Flow diagram 660 illustrates one embodiment of forming flexible substrates for use in photovoltaics; however, other embodiments of forming flexible substrates are also contemplated. In another embodiment, it is contemplated that the adhesive may be applied to the metal foil instead of the flexible backsheet. In yet another embodiment, it is contemplated that the metal foil may be shaped ahead of the guide roller instead of downstream of the guide roller along path A. In yet another embodiment, it is contemplated that either or both of steps 665 and 666 may occur prior to step 661. In such an embodiment, the laser may be selected to shape both the metal foil and the interlayer dielectric material. Additionally, it is also contemplated that shaping of the metal foil in step 663 may occur when both the metal foil and the flexible backsheet are stationary, as opposed to when both the metal foil and the flexible backsheet are in motion, as described above.

In yet another embodiment, it is contemplated that the metal foil may be shaped with the laser in a stationary position. An adhesive may then be applied to the shaped metal foil or a flexible backsheet, and the flexible backsheet can be disposed on the shaped metal foil to adhere the shaped metal foil to the flexible backsheet.

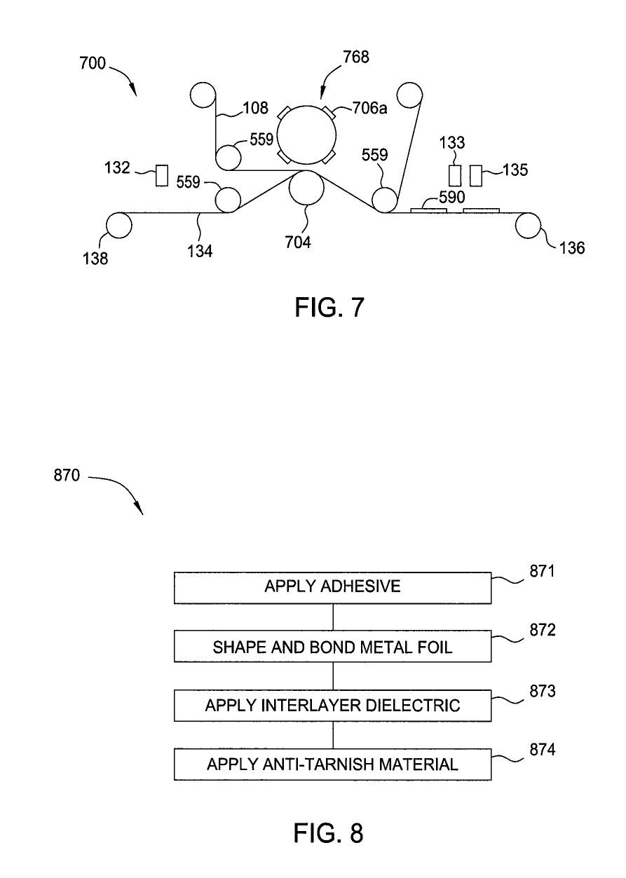

FIG. 7 is a schematic illustration of a system 700 for forming flexible substrates according to another embodiment of the invention. The system 700 includes a rotary die 768, a support roller 704, an adhesive applicator 132, a dielectric applicator 133, an anti-tarnish applicator 135, and guide rollers 559. A flexible backsheet 134 positioned on a feed roller 138 and a take-up roller 136 is guided by guide rollers 559 between the rotary die 768 and the support roller 704. An adhesive applicator 132, such as a screen printer, is positioned upstream of the rotary die 768 and the support roller 704 and is adapted to apply a patterned adhesive to the upper surface of the flexible backsheet 134.

The rotary die 768 is positioned down stream of the adhesive applicator 132 and above the support roller 704. The rotary die 768 is a cylindrical drum adapted to rotate at the same rate of travel as the metal foil 108 and the flexible backsheet 134. The rotary die 768 includes shaping portions 706a connected to the outer surface thereof. The shaping portions 706a are adapted to form a desired shape into the metal foil 108 as the metal foil 108 and the flexible backsheet 134 pass between the rotary die 768 and the support roller 704. The shaping portions 706a may be punches to punch the metal foil, or may be blades to cut to the metal foil. The rotary die 768 and the support roller 704 are positioned sufficiently close together activate the pressure sensitive adhesive and adhere the shaped metal foil 590 to the flexible backsheet 134. A dielectric applicator 133 and an anti-tarnish applicator 135 are positioned downstream of the rotary die 768 and the support roller 704, and are adapted to apply an interlayer dielectric and an anti-tarnish material, respectively.

FIG. 8 illustrates a flow diagram 870 of a method of forming a flexible substrate using the system 700 shown in FIG. 7 according to one embodiment of the invention. In step 871, an adhesive applicator applies a pressure sensitive adhesive in a desired pattern to the upper surface of a flexible backsheet as the flexible backsheet is unrolled from a feed roller. In step 872, a rotary die shapes the metal foil. The metal foil is shaped by the rotary die using shaping portions which remove sections of the metal foil (to form the shaped metal foil) as the metal foil travels between the rotary die and the support roller. The rotary die and the support roller compress the shaped metal foil, the flexible backsheet, and the pressure sensitive adhesive therebetween to bond the shaped metal foil to the upper surface of the flexible backsheet. After the shaped metal foil is bonded to the flexible backsheet, the remaining metal foil is wound around the metal foil take-up roller, and the flexible backsheet having the shaped metal foil thereon is positioned adjacent to a dielectric applicator.

In step 873, an interlayer dielectric material is printed on the shaped metal foil using a dielectric applicator. The interlayer dielectric is applied in a pattern substantially covering the shaped metal foil; however, openings are left therethrough to allow for electrical connections between the shaped metal foil and a solar cell subsequently positioned over the shaped metal foil. In step 874, an anti-tarnish material, such as copper, is positioned on the shaped metal foil in the areas not covered by the interlayer dielectric to prevent oxidation of the exposed areas of the shaped metal foil.

Flow diagram 870 describes one embodiment of forming flexible substrates; however, other embodiments of forming flexible substrates are also contemplated. In another embodiment, the metal foil may be bonded to a first flexible backsheet prior to step 871. In such an embodiment, as the metal foil and the first flexible backsheet pass between the rotary die and the support roller in step 872, only the metal foil is shaped while the first flexible backsheet remains substantially unshaped. The depth of the shape can be determined by adjusting the size of the shaping portions on the outer surface of the rotary die. During the metal foil shaping, the shaped metal foil and the first flexible backsheet may optionally be bonded to second flexible backsheet, such that a surface of the shaped metal foil is exposed (e.g., the first flexible backsheet is bonded to the second flexible backsheet). In this embodiment, because the first flexible backsheet is utilized as a carrier, shaping of the metal foil and bonding of the second flexible backsheet need not occur simultaneously.

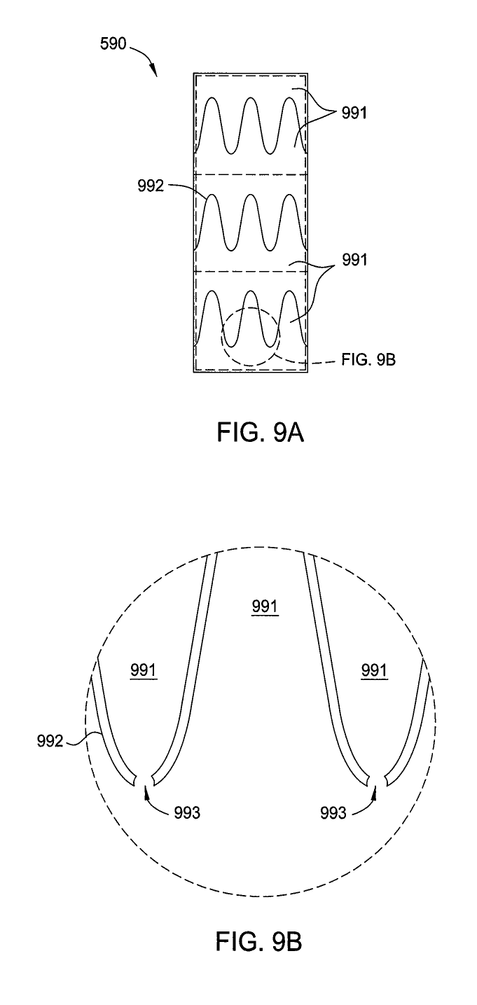

FIGS. 9A and 9B are schematic illustrations of a shaped metal foil 590 which may be formed according to embodiments of the invention. The shaped metal foil includes metal surfaces 991 and grooves 992. The grooves 992 are located where portions of metal foil have been removed, for example, by punching, pressing, or cutting. The grooves 992 are formed through the shaped metal foil 590 to separate and electrically isolate the metal surfaces 991.

The dashed-lines shown in FIG. 9A indicate the position of solar cells which may be positioned over the shaped metal foil 590 in the final manufactured device. Although the solar cells will generally cover the surface of the shaped metal foil 590, the dashed-lines are shown as having an area slightly smaller than the area of the shaped metal foil 590 in order to more clearly illustrate the shaped metal foil 590. However, it is contemplated that the area of the shaped metal foil 590 and the solar cells positioned thereon can be adjusted according to process specifications.

Generally, the back contacts of one polarity of a solar cell are positioned on one side of the groove 992 of the shaped metal foil 590, while the back contacts of the opposite polarity are positioned on the other side of the groove 992. The shaped metal foil 590 as shown in FIG. 9A is adapted have 3 solar cells positioned thereon in the final manufactured device. However, it is contemplated that the shaped metal foil 590 may be formed to accommodate more than 3 solar cells, for example, about 12 solar cells to about 72 solar cells, or more. In the example where the shaped metal foil 590 is adapted to accommodate 12 solar cells, the shaped metal foil 590 may include four 1×3 strips of shaped metal foil to form a 12 solar cell array. In such an embodiment, the shaped metal foil 590 may be shaped in a single step (e.g., a single circuit for a 3×4 solar cell array), or may be shaped in four sub-circuits (e.g., four 1×3 circuit arrays) and subsequently combined on a flexible backsheet.

FIG. 9B illustrates an enlarged partial view of the groove 992 of the shaped metal foil 590 according to one embodiment. Separate metal surfaces 991 are connected to one another by metal tabs 993 which bridge the grooves 992. The metal tabs 993 are areas of metal foil which are not removed when the grooves 992 are shaped into the foil. Thus, the shaped metal foil 590 remains a unitary piece held together by the metal tabs 993. The metal tabs 993 assist in the handling of the shaped metal foil 590, especially in embodiments where the metal foil is not bonded to a flexible backsheet at the time of shaping.

The metal tabs 993 assist in handling the shaped metal foil 590; however, the metal tabs 993 should generally be removed prior to completion of the final device to allow for electrical isolation between the separate metal surfaces 991. The metal tabs 993 may be removed using a mechanical device, such as a drill or blade, or by using a laser. It is contemplated that the mechanical device or the laser may also scribe through a flexible backsheet bonded to the backside of the shaped metal foil 590 when removing the metal tabs 993. Scribing through the flexible backsheet is generally acceptable, especially if a weather protection layer, such as aluminum foil, is to be bonded to the flexible backsheet thereafter.

Although the shaped metal foil 590 is shown as having the metal tabs 993, it is contemplated the shaped metal foil 590 may be formed without the metal tabs 993. Thus, electrical isolation between the metal surfaces 991 is provided at the time of shaping due to the formation of a complete groove.

Embodiments described herein generally refer to a metal foil formed from aluminum; however, other materials are contemplated. For example, the shaped metal foil may be a copper foil having a thickness within a range from about 10 microns to about 40 microns. Alternatively, the metal foil may be an aluminum foil having a layer of copper disposed thereon. In such an embodiment, the copper is generally sputtered onto the aluminum prior to shaping the metal foil and prior to application of an interlayer dielectric or an anti-tarnish material. Further, when the exposed surface of the metal foil is copper (for example, when using a copper foil or a copper-coated aluminum foil), an anti-tarnish material may be unnecessary.

Additionally, although embodiments described herein generally use pressure sensitive and UV curable adhesives, other adhesives are contemplated. For example, it is contemplated thermally-curable adhesives may also be utilized. Adhesives which are used according to embodiments described herein should be selected such that the adhesives do not provide significant out-gassing. Additionally, it is contemplated that pressure sensitive adhesives may be used in place of UV curable adhesives, and vice versa. When alternative adhesives are utilized in the methods described above, it is to be understood that appropriate changes to a respective flexible substrate forming apparatus may be needed.

Furthermore, embodiments herein generally refer to a flexible backsheet of PET, however, other flexible backsheet materials are contemplated. For example, it is contemplated that the flexible backsheet may be formed from polyvinyl fluoride, polyester, polyimides, or polyethylene. Additionally, it is contemplated that the flexible backsheet may also have a metal layer, such as aluminum, bonded to the surface opposite of the shaped metal foil in order to provide environmental protection.

Also, although copper is generally used herein as an anti-tarnish material, it is contemplated that other materials, such as organic resins, may also be used.

Benefits of the invention include lower cost alternatives to forming flexible substrates for use in photovoltaic manufacturing. By utilizing die cutting, punching, or laser cutting processes to form shaped metal foils, the use of consumable materials for patterning the foils is reduced, thus providing a significant cost savings. Additionally, the shaping techniques discussed herein allow for shaping of large-area metal foils, which improves production throughput.

While the foregoing is directed to embodiments of the present invention, other and further embodiments of the invention may be devised without departing from the basic scope thereof, and the scope thereof is determined by the claims that follow.

We claim:

1. A substrate for interconnecting photovoltaic devices, comprising:
a backsheet comprising a first polymeric layer that has a mounting surface;
a patterned adhesive layer comprising a plurality of adhesive regions that are disposed on the mounting surface;
a plurality of shaped metal foil elements that are disposed over the formed adhesive regions;
an interlayer dielectric material disposed on at least a first portion of each of the plurality of shaped metal foil elements; and
an anti-tarnish material disposed on a second portion of each of the plurality of shaped metal foil elements.

2. The substrate of claim 1, wherein each of the plurality of shaped metal foil elements comprise an aluminum foil layer having a front surface and a rear surface, and a copper layer disposed over the front surface, wherein the interlayer dielectric material is disposed on at least a portion of the copper layer.

3. The substrate of claim 1, wherein the interlayer dielectric material comprises acrylic or phenolic.

4. The substrate of claim 1, wherein the first polymeric layer comprises a material selected from a group consisting of polyethylene terephthalate (PET), polyvinyl fluoride (PVF), polyester, polyimides and polyethylene.

5. The substrate of claim 4, wherein the backsheet further comprises a second polymeric layer, and an adhesive layer disposed between the first polymeric layer and the second polymeric layer, and the second polymeric layer comprises a material selected from a group consisting of polyethylene terephthalate (PET), polyvinyl fluoride (PVF), polyester, polyimides and polyethylene.

6. The substrate of claim 1, wherein the patterned adhesive layer comprises a pressure sensitive adhesive.

7. The substrate of claim 6, wherein the patterned adhesive layer is applied to the mounting surface by a screen printing or ink jet printing process.

8. A substrate for interconnecting photovoltaic devices, comprising:
a backsheet comprising a first polymeric layer that has a mounting surface;
a patterned adhesive layer comprising a plurality of adhesive regions that are disposed on the mounting surface;
a plurality of shaped metal foil elements that are disposed over the formed adhesive regions;
an interlayer dielectric material disposed on at least a first portion of each of the plurality of shaped metal foil elements; and
an anti-tarnish material disposed on a second portion of each of the plurality of shaped metal foil elements, wherein the second portion of each of the plurality of shaped metal foil elements are not covered by the interlayer dielectric material, and each of the plurality of shaped metal foil elements comprise an aluminum foil layer having a front surface and a rear surface and a copper layer disposed over the front surface.

9. The substrate of claim 8, wherein the interlayer dielectric material comprises acrylic or phenolic.

10. The substrate of claim 8, wherein the first polymeric layer comprises a material selected from a group consisting of polyethylene terephthalate (PET), polyvinyl fluoride (PVF), polyester, polyimides and polyethylene.

11. The substrate of claim 10, wherein the backsheet further comprises a second polymeric layer, and an adhesive layer disposed between the first polymeric layer and the second polymeric layer, and the second polymeric layer comprises a material selected from a group consisting of polyethylene terephthalate (PET), polyvinyl fluoride (PVF), polyester, polyimides and polyethylene.

12. The substrate of claim 8, wherein the patterned adhesive layer comprises a pressure sensitive adhesive.

13. The substrate of claim 12, wherein the patterned adhesive layer is applied to the mounting surface by a screen printing or ink jet printing process.

14. A method of forming a substrate for interconnecting photovoltaic devices, comprising:
positioning a metal foil within a punch press;
actuating the punch press to form a shaped metal foil;
positioning a flexible backsheet adjacent to the shaped metal foil within the punch press;
applying an adhesive to the flexible backsheet or the shaped metal foil; and
applying pressure to the flexible backsheet, the shaped metal foil, and the adhesive to adhere the shaped metal foil to the flexible backsheet.

15. The method of claim 14, wherein applying the adhesive comprises screen printing the adhesive on the flexible backsheet.

16. The method of claim 14, wherein applying pressure comprises actuating the punch press to apply pressure to the flexible backsheet, the shaped metal foil, and the adhesive located therebetween.

17. The method of claim 14, further comprising applying a vacuum through openings disposed in the punch press to adhere the metal foil to the punch press.

18. The method of claim 14, wherein the flexible substrate comprises polyethelene terephthalate, and the metal foil comprise aluminum.

19. A method of forming a substrate for interconnecting photovoltaic devices, comprising:
applying an adhesive to the upper surface of a flexible backsheet;
positioning the flexible backsheet with the adhesive thereon adjacent to a metal foil;
shaping the metal foil using a laser to form a shaped metal foil;
disposing the shaped metal foil on the adhesive;
bonding the shaped metal foil to the flexible backsheet;
disposing an interlayer dielectric on the shaped metal foil, the interlayer dielectric having openings therethrough; and
disposing an anti-tarnishing material on the shaped metal foil within the openings of the interlayer dielectric layer.

20. The method of claim 19, wherein positioning the adhesive adjacent to a metal foil comprises rolling the flexible backsheet between a feed roller and a take-up roller.

21. The method of claim 19, wherein the metal foil comprises aluminum having a copper coating thereon.

22. A method of forming a substrate for interconnecting photovoltaic devices, comprising:
positioning a flexible backsheet and a metal foil between a support roller and rotary die;
disposing an adhesive on the flexible backsheet;
shaping the metal foil using the rotary die;
adhering the shaped metal foil to the flexible backsheet while passing the flexible backsheet, the shaped metal foil, and the adhesive between the support roller and the rotary die;
applying an interlayer dielectric to the shaped metal foil, the interlayer dielectric having openings therethrough; and
applying an anti-tarnishing material to the shaped metal foil through the openings in the interlayer dielectric.

23. The method of claim 22, wherein the flexible backsheet comprises polyethelene terephthalate.

24. The method of claim 22, wherein the metal foil comprises aluminum and the anti-tarnish comprises copper.

25. The method of claim 22, wherein the metal foil comprises copper having a thickness within a range of about 10 microns to about 40 microns.

26. The method of claim 22, wherein the shaped metal foil has grooves and metal tabs bridging the grooves.
